(19) United States
(12) Patent Application Publication
(10) Pub. No.: US 2010/0038656 A1
(43) Pub. Date: Feb. 18, 2010

(54) Nitride LEDs based on thick templates

(75) Inventors: Scott M. Zimmerman, Basking Ridge, NJ (US); Karl W. Beeson, Princeton, NJ (US)

Correspondence Address: Goldeneye, Inc.;Suite 233, 9747 Businesspark Avenue, San Diego, CA, 92131, US

(73) Assignee: Goldeneye

(21) Appl. No.: 12/462,381

(22) Filed: Aug. 3, 2009

Related U.S. Application Data
(60) Provisional application No. 61/188,013, filed on Aug. 4, 2008.

(51) Int. Cl. H01L 33/00; H01L 29/20; H01L 31/0232; H01L 21/302

(52) U.S. Cl. 257/88; 257/615; 257/435; 438/463; 257/98; 257/E29.089; 257/E33.067; 257/E31.127; 257/E21.214

(57) ABSTRACT

Thick HVPE templates of nitrides enhance both the growth conditions and resulting device performance of LEDs, power devices, solar cells, and other electrical elements. The use of HVPE templates greater than 15 microns allows for increased incorporation of indium and/or aluminum in alloys with gallium nitride relative to a thinner MOCVD template for a given reactor growth temperature. The use of these thicker templates further allows the formation of epitaxial chips. The use of this approach forms more efficient nitride devices between 520 nm and 1.7 microns. These devices may be used for both emitting and absorbing applications such as LEDs and solar cells.

### REFERENCE TO PRIOR APPLICATION

This application claims the benefit of U.S. Provisional Patent Application Ser. No. US61/188,013, which was filed on Aug. 4, 2008, which is herein incorporated by reference.

### BACKGROUND OF THE INVENTION

Nitrides have become the dominant material in solid state lighting. Gallium nitride (GaN) in particular offers superior properties for operation in the near UV and blue spectral region. Various alloys based on adding indium and/or aluminum are used to extend the operational range of GaN up into the UV and into the green portion of the visible spectrum. Operation in the yellow, orange and red portion of the spectrum are somewhat limited due to the low IQE of devices made using nitrides. As such, aluminum indium gallium phosphide (AlInGaP) is used for amber and red emitters.

Unfortunately, AlInGaP suffers from thermal and current saturation effects at much lower levels than nitrides. AlInGaP also exhibits a broad absorption spectrum in the visible due to its low band-edge, which limits its ability to form efficient yellows and greens. The absorptive nature of AlInGaP also severely limits its usage with blue and green emitters due to strong absorption of these wavelengths by the AlInGaP material itself.

As stated earlier, nitrides however do not operate efficiently in the yellow, orange and red regions for a variety of reasons. This has resulted in the so called “Green Gap”. This typically designates a spectrum roughly between 520 nm and 620 nm in which neither nitrides or AlInGaP can operate efficiently. Various materials have been proposed to bridge this gap including dilute nitrides and zinc oxide (ZnO). Advantages and disadvantages abound for each material. However, in many cases the use of single material set that could cover the whole spectral range of a particular device would be ideal especially for white light sources, solar applications, and other broadband devices. More specifically, broadband optical designs, which use materials exhibiting a band-edge within the operational spectral range, limit the overall performance of the device. Recycling cavities, solar cells, and white light sources all must compromise efficiency due to absorption losses if a low band-edge component is used.

Nitrides at first glance would appear to be able to span the entire range of the UV, visible and near IR spectrum. Indium nitride (InN) has a band-edge at 0.7 eV while aluminum nitride (AlN) is up at 6.0 eV with GaN in between at 3.2 eV. It would appear possible to create alloys that operate from 1.5 microns to almost 200 nm. However, high crystal quality material is not available covering all the possible alloy compositions. This is especially true for indium gallium nitride (InGaN) alloys due to the limited range of growth conditions that can be used to incorporate high concentrations of indium into the crystal and still maintain reasonable crystal quality. Aluminum gallium nitride (AlGaN) is also limited with regard to crystal quality at high aluminum concentrations. Adding in the various dopants required to create n type, p type, and semi-insulating properties only further complicates the problem.

The lack of high crystal quality material has created a number of false assumptions with regard to basic nitride properties. As an example, GaN is typically reported to have a thermal conductivity of around 120 W/m/K. Recently, it has been shown that as defect density and impurities are decreased, the thermal conductivity of GaN can exceed 200 W/m/K and may eventually be higher than silicon carbide (SiC). The need therefore exists for enhanced crystal quality nitride alloys.

Unfortunately, nitrides do not lend themselves to boule type growth approaches. Even if such a process were developed, the cost of these wafers would be prohibitive due to the extreme growth conditions required. Recently, templates based on HVPE growth techniques have created the opportunity for low cost relatively thick nitride growth substrates. These templates have typically been used to reduce the cost of manufacture by reducing the time the wafer must be in the MOCVD reactor. In this case, 3 to 5 micron thick n-GaN is typically grown on the sapphire wafer using HVPE. The rest of the structure is then grown via MOCVD.

The present inventors have previously disclosed the use of thick HVPE templates and methods of forming epitaxial chips based on these thick HVPE templates to enhance LED, solar cell, and electronic device performance. This is based on the ability to create freestanding all nitride devices, eliminate thermal interfaces, and reduce absorption losses due to the lower average alpha of HVPE versus MOCVD. The use of thick HVPE templates enables reduced cost. HVPE can be used to increase extraction efficiency by reduced absorption within the epitaxial layers themselves. Inherent to MOCVD growth is the incorporation of carbon impurities, which contribute to higher alpha relative to HVPE. In addition, the cost of forming thick layers via MOCVD is cost prohibitive due to the low growth rate.

In the process of comparing MOCVD and HVPE templates of various thicknesses, the present inventors have discovered that one can control both growth rate and alloy composition by varying the thickness of the templates and temperature profiles at the surface of the template during MQW growth. Using these techniques, one can not only extend the useful operational range of nitrides but also create novel spatially varying emitters using these cost effective thick HVPE templates. Lawrence Berkeley National Labs compared 5 micron MOCVD templates to 15 micron MOCVD templates and saw a 0.132 eV shift in the spectrum for Blue LEDs (480 nm to 506 nm) which they attributed to reduced surface stresses of thicker templates. They however failed to take into account the effect of lower surface temperature for a thick template versus a thinner template. Since growth rate and indium incorporation is strongly a function of the surface temperature, the results of this study is inconclusive. Conversely, other authors have indicated that formation of strained InGaN layers can be used to red shift the operation point of the MQWs supposedly due to enhanced indium incorporation. Based on comparisons between thin MOCVD and thick HVPE templates, the present inventors have shown that emission and absorption spectra devices grown on thick HVPE templates can be increased or decreased relative to the thinner MOCVD template by controlling the surface temperature profiles of the template spatially.

Typically, a thick template provides higher concentration of indium and/or aluminum and higher growth rates in the same run than a thinner MOCVD template. However, the present inventors have shown using warped wafers that both shorter and longer emission can be created than a thinner flat MOVCVD control wafer. In fact, single 2 inch wafers with emission from 410 nm to 590 nm have been demonstrated. 5 micron MOCVD wafer in the same run exhibited emissions between 430 nm and 450 nm. 30 micron thick HVPE wafers, which are flat at the growth temperature, exhibited emission between 460 and 480 nm. Clearly, actual surface temperature, surface stress, and possibly crystal quality differences between MOCVD templates and HVPE templates all play a role in device performance.

The intent of this invention is to show how low cost thick HVPE templates can be used to enhance the overall device performance of nitrides at longer wavelengths, shorter wavelengths, and create spatially varying devices for enhanced solar and lighting applications. Since nitride alloys also have applicability in power electronics and RF devices, these techniques and improved nitride alloys can be used in these devices. The incorporation of dopants also can be enhanced using these techniques as well. A thick HVPE template appears to increase the amount of indium which can be incorporated at a given reactor growth temperature and also the lower alpha of the HVPE template enhances extraction efficiency. The combination of these attributes extends the operational range of nitrides by enabling higher crystal quality nitride alloys of aluminum, indium, and gallium and improving extraction efficiency as well. The use of alloy HVPE templates to move up and down the spectral range between 0.7 eV and 6.0 eV is also disclosed.

### SUMMARY OF THE INVENTION

This invention discloses the use of thick HVPE templates of nitrides to enhance both the growth conditions and resulting device performance of LEDs, power devices, solar cells, and other electrical elements. More preferably, this invention discloses the use of HVPE templates greater than 15 microns to allow for increased incorporation of indium and/or aluminum in alloys with gallium nitride relative to a thinner MOCVD template for a given reactor growth temperature. The use of these thicker templates further allows the formation of epitaxial chips. Freestanding epitaxial chips are formed as it appears that device stresses play a significant role in device performance. The emission spectrum of bonded versus freestanding epitaxial chips is different due to the relaxation of stresses. Even more preferably, the ability to increase reactor growth temperature for a given alloy composition enhances crystal quality of that particular alloy and optionally any subsequent growths. The combination of low alpha of the thick HVPE and/or enhanced growth and/or modification of nitride alloy composition can create more efficient optical, electrical, and optoelectronic devices.

The use of this approach forms more efficient nitride devices between 520 nm and 1.7 microns. These devices may be used for both emitting and absorbing applications such as LEDs and solar cells. Higher indium concentration InGaN is grown on thick HVPE templates versus thinner MOCVD templates under the identical reactor growth conditions. More specifically, 15 micron HVPE templates exhibit over 10% higher indium concentration compared to 5 micron MOCVD templates. 30 micron HVPE templates exhibit even higher indium concentration levels under identical reactor growth conditions. The use of these thicker HVPE templates also enables the formation of low cost freestanding epitaxial chips by eliminating the need for wafer bonding. Growth rates also increase using thicker templates as well. This provides a cost effective route to growing higher indium concentration InGaN at higher reactor growth temperatures on thick templates than is possible on sapphire alone or thin MOCVD templates.

The thick HVPE templates are themselves an embodiment of this invention. Thick HVPE template which exhibits less than 50 microns of bow on a 2 inch wafer at room temperature will facilitate uniform liftoff. An HVPE template greater than 15 microns with a surface quality can be epitaxial ready as grown. This template eliminates the need for extra polishing and cleaning steps, which tend to introduce defects and increase costs. At a given reactor growth temperature of the MQWs, bow can be tailored to be flat across the wafer or not flat. By adjusting this bow and pocket surface profile within the reactor platen, a variety of surface temperature profiles can be created. Both the templates exhibiting these characteristics and the shaping of the platen are embodiments of this invention. Templates with the elimination/reduction of backside growth can facilitate laser liftoff. Templates can have epitaxial thickness greater than 1/10 the smallest lateral dimension of the device. Even more preferred is a thickness greater than 10 microns to enable the use of backside scribing and liftoff. The use of this technique eliminates streeting/kerf losses.

Further devices formed based on this discovery can create higher efficiency nitride devices that can be emitters and/or absorbers with enhanced operation range. By controlling the temperature profile across the wafer, emitting or absorbing devices can be created that vary continuously across the wafer. A single wafer can exhibit PL peak wavelength emission from 417 nm to 589 nm. The emitting and absorbing devices will have continuous spatially varying properties across their surface. The formation of epitaxial chips based on these wafers is also an embodiment of this invention.

### BRIEF DESCRIPTION OF THE DRAWINGS

FIG. 1 depicts indium concentration in InGaN versus growth temperature for a 5 micron MOCVD and a 15 micron HVPE templates of the present invention.

FIG. 2 depicts thickness variation of quantum well for a 5 micron MOCVD template versus a 30 micron HVPE template of the present invention.

FIG. 3 depicts a graph of peak lambda via PL map ranging from 417 nm to 585 nm on a 2 inch wafer of the present invention.

FIG. 4 depicts a white LED die with a spatially varying emission of the present invention.

FIG. 5 depicts a solar cell with a continuously spatially varying absorption spectrum of the present invention.

FIG. 6 depicts a solar concentrator with wavelength specific optical element which directs the appropriate wavelength from the sun onto the appropriate portion of the continuously spatially varying absorption solar cell of the present invention.

FIG. 7 depicts the use of high reflectivity red nitride LED within a recycling cavity of the present invention.

FIG. 8 depicts the use of high reflectivity red nitride LED along with a blue nitride LED and Ce:Yag solid luminescent element to provide an enhanced CRI light source of the present invention.

FIG. 9 depicts an all nitride orange epitaxial chip formed using a thick HVPE template of the present invention.

FIG. 10 depicts an all nitride epitaxial chip with a spatially varying emission spectrum of the present invention.

FIG. 11 depicts electron beam modification of the surface of an HVPE template to vary emission wavelength of an LED of the present invention.

FIG. 12 depicts a shaped platen pocket that varies the temperature of the wafer during growth of the present invention.

FIG. 13 depicts backside scribing and liftoff to eliminate streeting/kerf losses of the present invention.

FIG. 14 depicts a greater than 15 microns thick HVPE template on double side polished sapphire with less than 50 micron at room temperature with a surface roughness less than 100 angstroms measured on a 5 micron by 5 micron field of the present invention.

FIG. 15 depicts a greater than 10 microns thick HVPE template with less than 100 microns bow at room temperature and less than 100 microns bow at growth temperature of MQWs of the present invention.

FIG. 16 depicts a greater than 10 micron thick HVPE template on sapphire with minimal amount of backside growth of the present invention.

FIG. 17 depicts a doped ZnO current spreading layer greater than 3000 Angstroms to control cracking of the present invention.

### DETAILED DESCRIPTION OF THE INVENTION

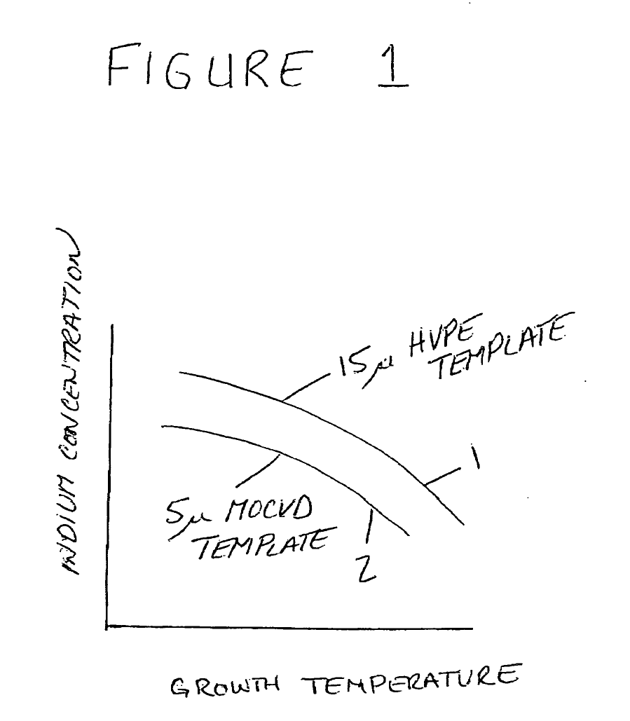

FIG. 1 depicts the indium concentration versus reactor growth temperature. Curve 1 for the 15 micron HVPE template shows a higher level of indium incorporated into the InGaN alloy being grown for a given reactor growth temperature than curve 2 which is the indium incorporated into the InGaN alloy being grown on 5 microns thick MOCVD template. The ability to create higher indium content alloys at a given reactor growth temperature enables the creation of longer wavelength devices without compromising crystal quality of not only the InGaN layer but also the other layers which may or may not be alloys. This further enhances device performance since subsequent layers such as AlGaN barriers and p type layers prefer higher growth temperatures for improved crystal quality. In addition, the higher MOCVD growth temperature of the quantum wells allows for the use of high temperature HVPE to form barrier and p layers without compromising the quantum wells. The use of thick HVPE templates elevates the MOCVD growth temperature such that HVPE barrier and p layers can be subsequently be grown.

Thick HVPE grown nitride layers in semiconductor structures enhance both the growth conditions and resulting device performance of LEDs, power devices, solar cells, and other electrical elements. The use of HVPE templates greater than 15 microns in semiconductor structures allows for increased incorporation of indium and/or aluminum in alloys with gallium nitride relative to a thinner MOCVD template for a given reactor growth temperature. The use of these thicker templates further allows the formation of epitaxial chips. The use of this approach forms more efficient nitride devices between 520 nm and 1.7 microns. These devices may be used for both emitting and absorbing applications such as LEDs and solar cells.

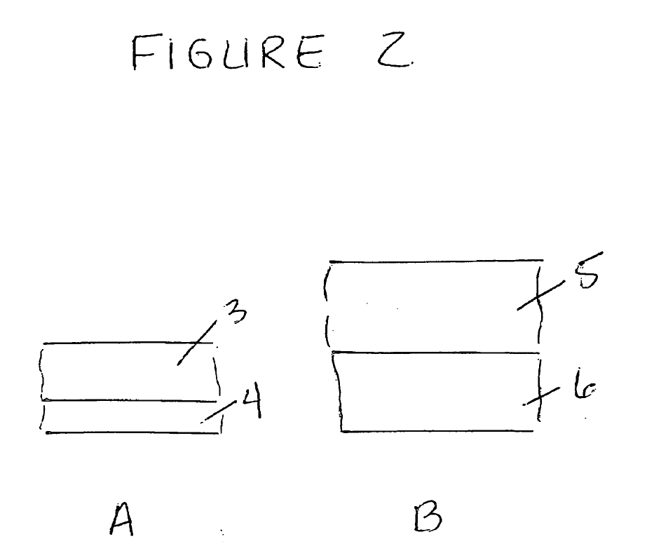

FIG. 2A depicts a typical quantum well grown on a 5 micron MOCVD template with InGaN layer 4 and GaN layer 3. FIG. 2B depicts a typical quantum well 5 grown on a 30 micron thick HVPE template 6. As stated in the previous figure, the amount of indium incorporated under identical growth conditions is higher in the case of the thicker HVPE template. In addition, as shown in FIGS. 2A and 2B the growth rate is enhanced for the HVPE case. The increased spacing of the quantum wells and increased indium concentration translate into a spectral shift in the quantum well itself.

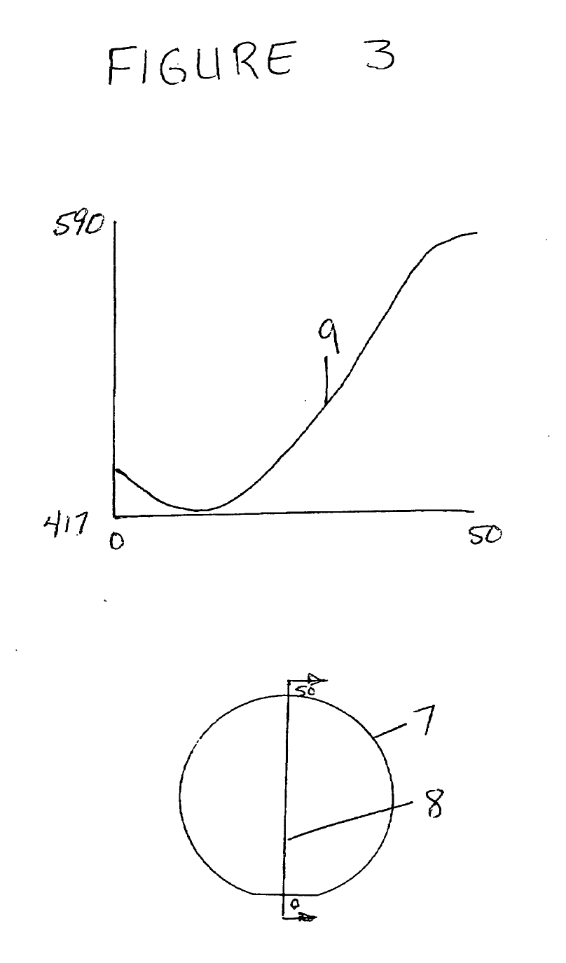

FIG. 3 depicts a single epitaxial growth on wafer 7 with a continuously varying peak wavelength curve 9 across the wafer 7 along axis 8. By varying the temperature across the wafer, it is possible to create a wide range of emission profiles. In this particular case, the PL varies from 417 nm to 590 nm. A 5 micron MOCVD template, which is flat at the reactor growth temperature, has a PL which ranges between and 430 nm and 450 nm. 30 micron thick HVPE templates, which are flat at the reactor growth temperature having the same growth conditions as the previous two templates, have PLs which range from 460 nm to 480 nm. The formation of the warped epitaxial layers yields EL outputs from the near UV to orange. Large area epitaxial chips previously disclosed by the authors enable the creation of die which emit continuously from deep blue to yellow.

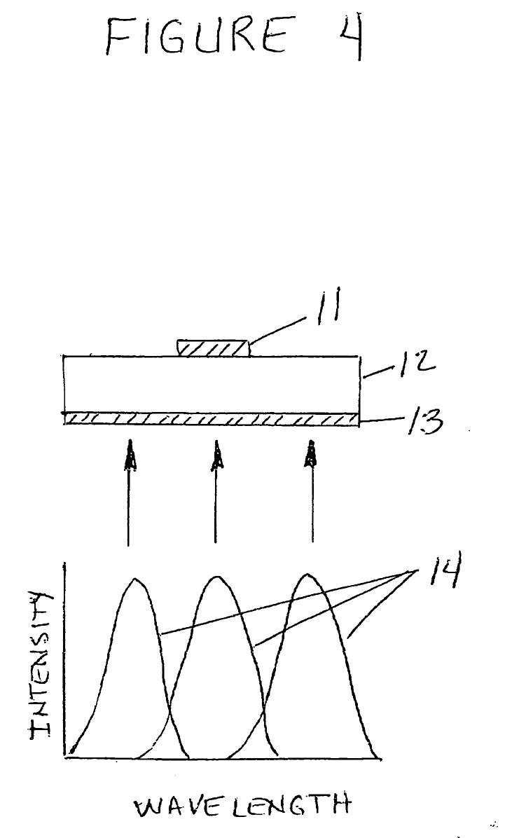

FIG. 4 depicts an LED 12 with top contact 11 and bottom contact 13. The chart shows how the spectrum 14 varies spatially across the LED 12. The chart depicts a discrete spectrum 14 for visualization only. The actual spectrum shift is continuous. In this manner, uniform spectrums can be created without the gaps typically associated with using a number of discrete devices. This can be used to create higher CRI sources or provide continuous sources for spectrometers, microscopes, and other instruments which rely on broad band sources.

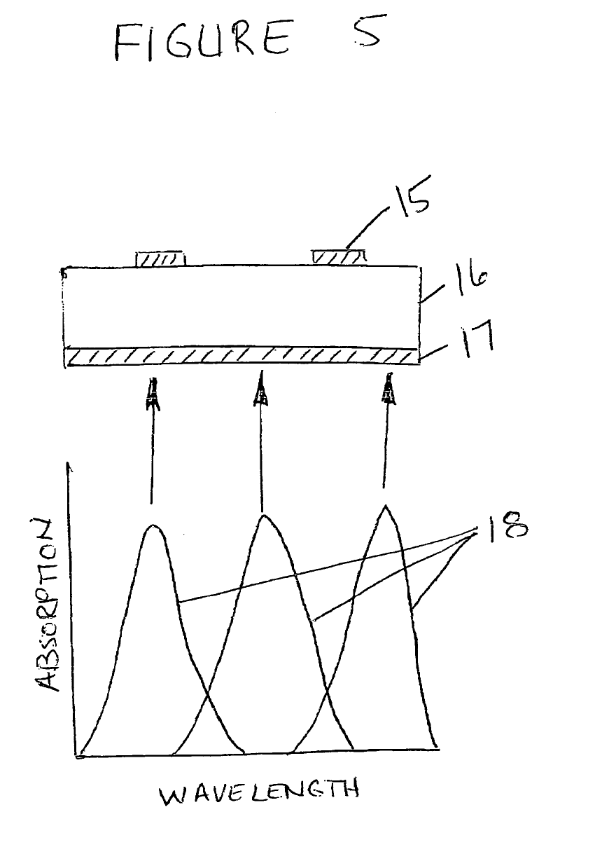

FIG. 5 depicts a solar cell 16 with top contact 15 and back contact 17. In this case, a continuous variation in absorption 18 is created such that the optimum wavelength for conversion varies across the solar cell 16. As in the previous figure, the change is continuous, not discrete, and the absorption curves 18 are for visualization only. The theoretical maximum efficiency of a single junction solar cell is around 25%. For this reason, stacked cells are typically used to increase the efficiency.

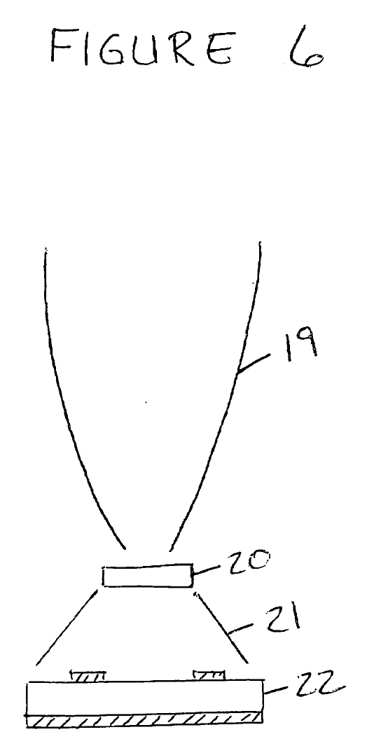

FIG. 6 depicts a concentrator 19 which may include but not limited to compound parabolic collectors, lens, Fresnel lens, troughs and mirrors. Wavelength dispersive element 20 may consist of reflective and transmissive gratings, photonic crystal, prisms, and subwavelength optical elements. The purpose of wavelength dispersive element 20 is to separate the concentrated light into rainbow 21. This rainbow 21 impinges on continuously varying absorption solar cell 22 such that maximum conversion efficiency can be obtained. The use of increase indium incorporation using thick HVPE templates as described earlier to extend the useful range of nitrides is an embodiment of this invention.

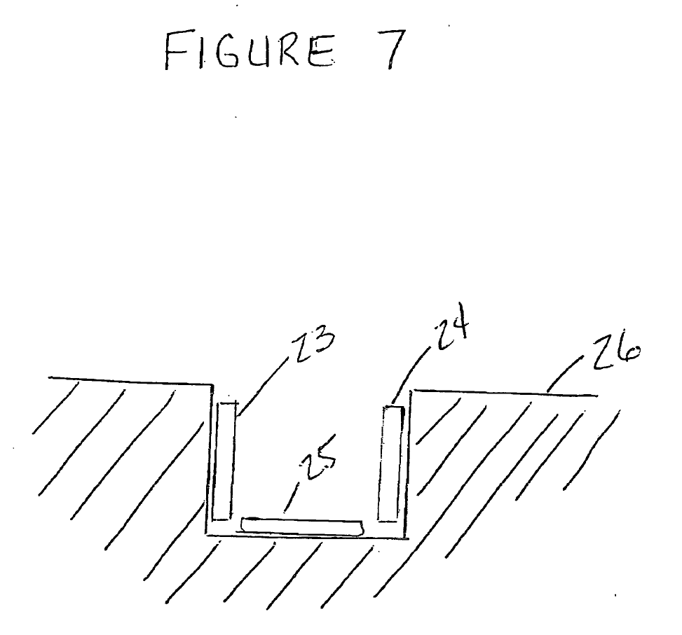

FIG. 7 depicts a recycling light cavity containing blue LED 23, green LED 24, and red LED 25 within cavity 26. If red LED 25 consists of AlInGaP or another material which exhibited strong absorption within the visible spectrum, the output of the recycling light cavity would be diminished as light from blue LED 23 and green LED 24 would be absorbed by red LED 25. It is an embodiment of this invention that red LED 25 be a nitride such that absorption losses are minimized. Alternately, the use of thick HVPE templates can incorporate more aluminum such that improved performance in the UV occurs.

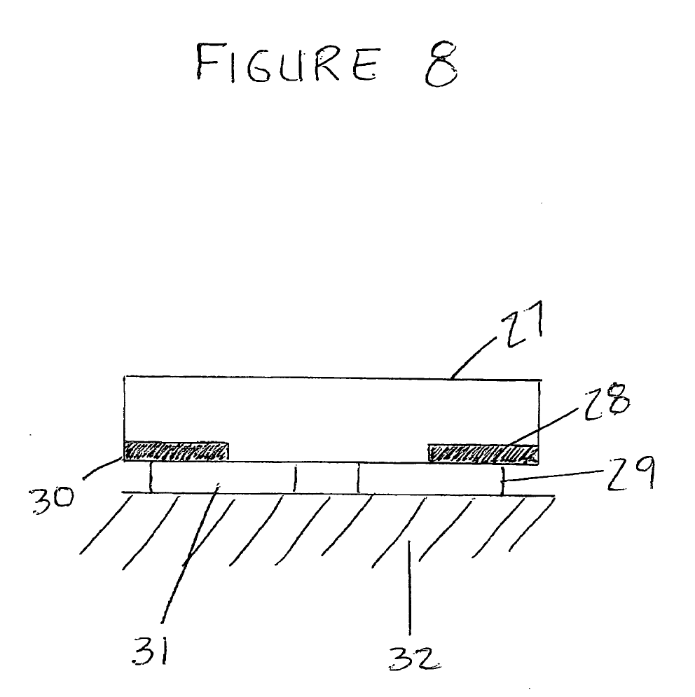

FIG. 8 depicts a white light source consisting of at least one luminescent element 27 which may include powdered phosphors, phosphors at a distance, phosphors in binders, solid luminescent elements (ceramic, single crystal, polycrystalline, and thin films), electrical contacts 28 and 30 and at least two LEDs 29 and 31. The two LEDs 29 and 31 can be mounted to heatsink 32. The two LEDs 29 and 31, more preferably, consist of a blue LED and a red highly reflective nitride LEDs. In this manner, absorption losses associated with using AlInGaP and other emitters with strong absorption in the blue and green regions of the spectrum can be eliminated.

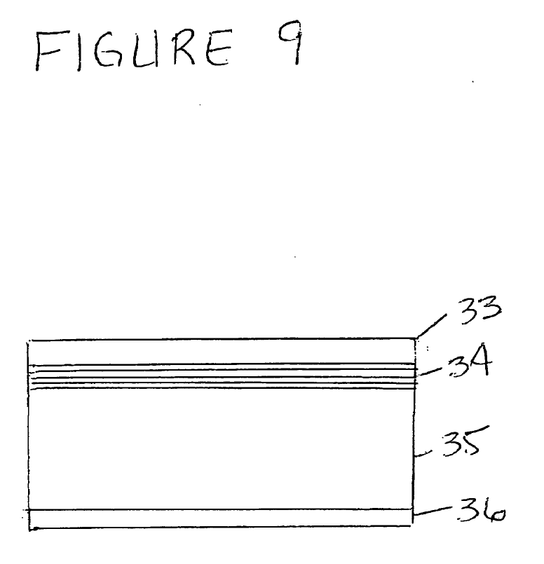

FIG. 9 depicts a epitaxial chip LED with transparent top contact 33 and transparent bottom contact 36, LED structure 34 is grown on HVPE template 35. The device emits at 585 nm. As stated earlier, emission from 6.2 to 0.7 eV is possible with nitrides. Using this configuration, the maximum extraction efficiency can be realized as well as the maximum internal quantum efficiency based on the previous structures disclosed. These devices can be transparent throughout the visible spectrum, unlike AlInGaP or dilute nitrides. This enables the stacking of chips without significant absorption losses.

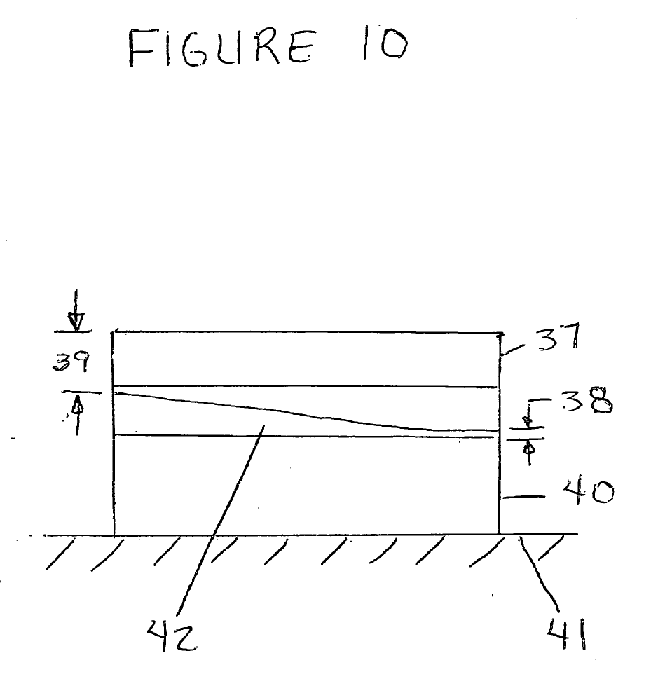

FIG. 10 depicts a broadband LED 40 comprising a transparent top electrode 37 and active region 42 that varies in thickness from dimension 38 to dimension 39 across the width of the device. Optionally, the device may be mounted on heatsink 41 for cooling and interconnect purposes. As described in earlier discussions, the variation in thickness correlates to variation in emission, thus a broader range of wavelengths can be emitted from a single device. The stacking of multiple broadband devices can further extend the emission range.

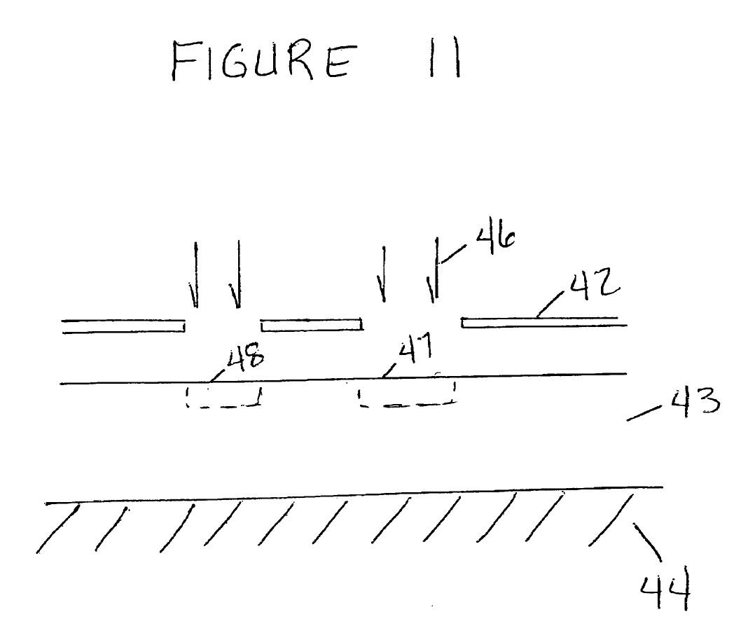

FIG. 11 depicts the use of actinic radiation 46 to spatially modify an epitaxial layer 43 to create growth regions 48 and 47. Optionally, the use of a masking element 42 may be used to pattern the epitaxial layer 43. Optionally, epitaxial layer 43 may be on a growth substrate 44. Actinic radiation 46 may include but not limited to laser, electron, x-ray, radiation sources, plasmas, reactive ions, and atomic species. The intent of this disclosure is to modify the surface stress of epitaxial layer 43 such that a subsequently grown alloy composition is modified for a given reactor growth condition. This technique creates spatially distinct emitters. More specifically the use of this technique creates color pixels for display applications.

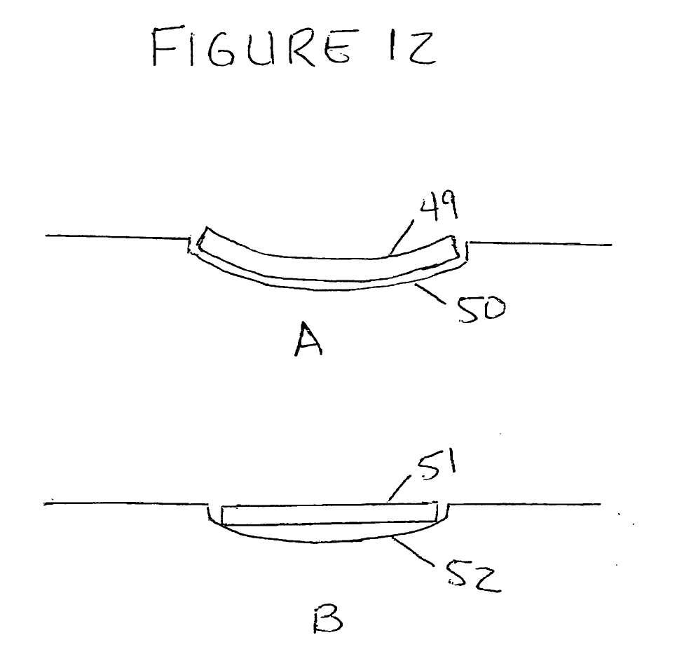

FIG. 12A depicts platen pocket 50 shaped such that bowed wafer 49 substantially conforms to the surface of platen pocket 50. In this manner, uniform heating can be created and the surface temperature profile of bowed wafer 49 can be more uniform. FIG. 12B depicts platen pocket 52 shaped such that flat wafer 51 does not contact uniformly. This creates a surface temperature profile on flat wafer 51 that varies according to the thermal gradient created. In addition, the use of the centrifugal forces generated by the spinning of the platen can be used to shift the thermal gradient as well by causing the wafer to more intimate physical contact to one region than another.

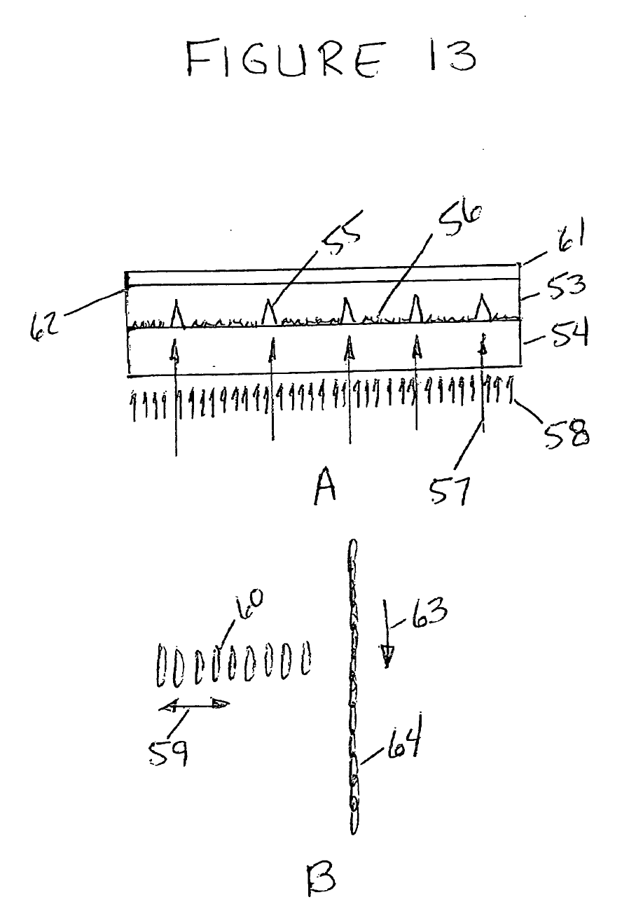

FIG. 13A depicts scribing and liftoff through a transparent growth substrate 54 of a thick epitaxial layer 53. The thickness of thick epitaxial layer 53 provides sufficient integrity such that both scribing and liftoff can be done through the growth substrate. This eliminates the need to touch the outer surface 61 of thick epitaxial layer 53. Typically, a number of masking, protective layers and etching steps are used to create mesas with streets on outer surface 61 between each device being fabricated. Alternately, diamond cutting and/or laser scribing are done on outer surface 61. This typically requires the use of chemical or reactive etching to remove slag or damage since the active layer 62 is in close proximity to outer surface 61. Both these approaches introduced extra cost both from processing time and steps, yield, and lost epitaxial area. By scribing and lifting off through the transparent growth substrate 54, both streeting and kerf losses can be eliminated. Also the processing steps are greatly reduced. Large areas, up to the size of the transparent growth substrate 54, can be removed, tested and further modified before the use of breaking means to form the final die sizes. More preferable, the thick epitaxial layer 53 has a thickness greater than 1/10 the shortest lateral dimension. Even more preferred, the thick epitaxial layer 53 has a thickness greater than 15 microns. Even more preferred, the thick epitaxial layer 53 consists of a thick HVPE template and at least one of the previously disclosed techniques for making enhanced nitride devices.

FIG. 13B depicts the use of two different scanning directions to determine streeting versus liftoff. As previously disclosed by the authors, narrow line sources 60 from a high rep rate DPSS laser can be scanned in direction 59 such that non-overlapping cuts can be created at the interface between transparent growth substrate 54 and thick epitaxial layer 53. This laser wavelength is selected such that absorption occurs at the interface between these two layers. In this manner, both extraction elements and/or stress release elements can be formed simultaneously with liftoff. This eliminates subsequent processing steps reducing cost and increasing yield. In this disclosure, the previously discussed processing steps relating to mesa formation and streeting are eliminated by the combination of backside streeting and the thick epitaxial layer 53. Because the thick epitaxial layer 53 in physically robust enough to be scribed from the backside without fracturing, the mesa and streeting steps are eliminated. The thickness of thick epitaxial layer 53 also can be used to physically separate the active layer 62 from the scribe line 55. Scribe line 55 must be sufficiently deep enough to permit a clean break or cleave but not so deep to effect the active region 62 performance. Using this approach, liftoff is created by scanning the line source 60 in direction 59. While scribing is done by scanning line source 64, which may or may not be the same as line source 60, in direction 63 such that line source 64 pulses overlap to create the deeper cut depth. This creates a substantially different profile as shown in scribe line 55 and liftoff/extraction/stress relief features 56. Liftoff/extraction element/stress relief radiation 58 and scribe line radiation 57 illustrates that the individual pulse energy can be the same or different depending on the characteristics of thick epitaxial layer 53, desired shape and depth of scribe line 55 and desired shape and depth of liftoff/extraction/stress relief features 56. Additionally, spacing and direction liftoff/extraction/stress relief features 56 and/or scribe line 55 pulses can be varied to modify the shape and/or depth of the features. Orientation of direction 59 for liftoff/extraction/stress relief features 56 to counter stresses in thick epitaxial layer 53 is preferred.

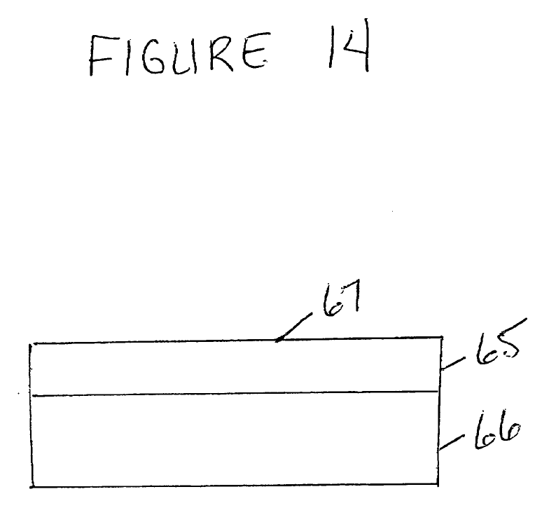

FIG. 14 depicts a 15 micron thick HVPE epitaxial layer 65 grown on double side polished sapphire substrate 66 with an as grown surface roughness less than 100 Angstroms RMS as measured on a 5 micron×5 micron field on outer surface 67. The use of miscut angles between 0 and 2 degrees will reduce surface roughness. The use of this template provides an epitaxial ready substrate for subsequent MOCVD and/or HVPE growth. More preferably, a 15 micron thick HVPE epitaxial layer 65 on double side polished sapphire 66 has less than 100 Angstroms RMS as measured on a 5×5 micron field with less that 100 microns absolute bow at room temperature. This template eliminates cleaning and polishing steps, which not only increase cost but introduce defects and contaminants.

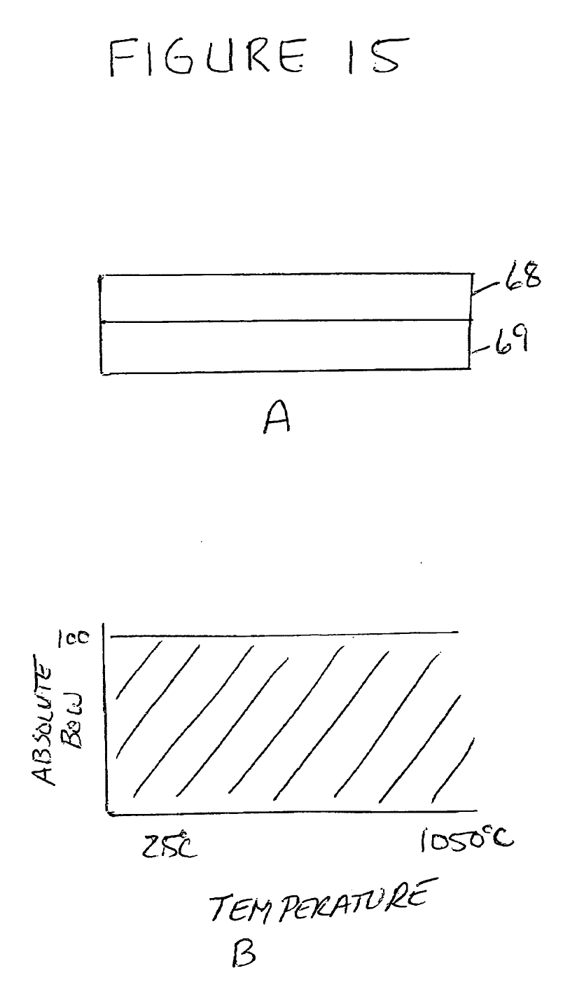

FIG. 15A depicts a thick HVPE epitaxial layer 68 grown on sapphire substrate 69 which exhibits an absolute bow less than 100 microns at both room temperature and reactor growth temperature. More preferably in FIG. 15B, a greater than 15 micron thick HVPE template grown on sapphire has less than 100 microns of absolute bow between 25 C and 1050 C. Even more preferred is a greater than 15 micron thick HVPE template grown on sapphire with less than 50 microns of absolute bow at liftoff temperature and essentially flat at reactor growth temperature. The requirement for flatness is based on limited depth of field of the laser pulses used in liftoff and the need for flatness at reactor growth temperature for the case where uniform device performance is desired. Since bow is ultimately related to lattice mismatch between the sapphire 69 and the particular nitride alloy of thick HVPE epitaxial layer 68, some compromise is typically required. Laser liftoff typically requires a maximum bow of less than 100 microns over a given wafer field to maintain focus. Alternately, if uniform device performance is required either the platen must be shaped to wafer bow at the growth temperature or bow must be minimized at the growth temperature. Bow can be used to vary device performance. Platen pocket shaping can be used to create uniform device performance to allow for minimal bow at laser liftoff conditions which is typically performed at room temperature.

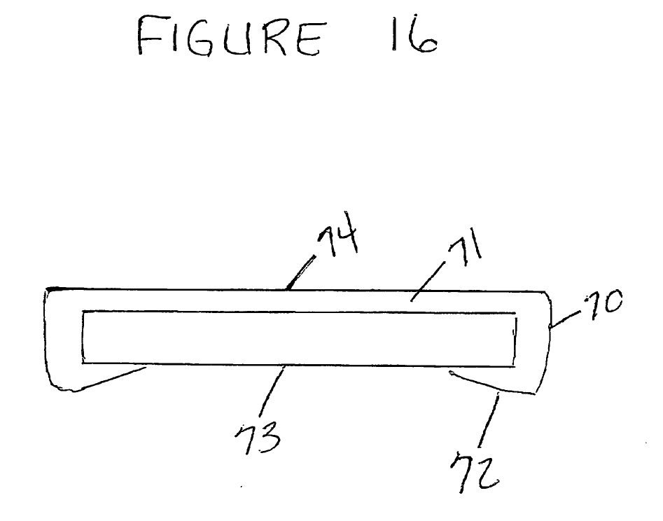

FIG. 16 depicts a thick HVPE epitaxial layer 71 grown on sapphire substrate 73. Typically, edge growth 70 and backside growth 72 occurs for thick layers. An embodiment of this invention is a greater than 15 micron HVPE template the substantially eliminates backside growth 72. This enables laser liftoff of the majority of thick HVPE epitaxial layer 71 without the need for backside polishing or removal means of backside growth 72. This is especially important to prevent contamination of top surface 74 since some type of supporting means is typically required to enable removal of backside growth 72. Removal or elimination is required because laser energy will couple into backside growth 72 and hinder liftoff.

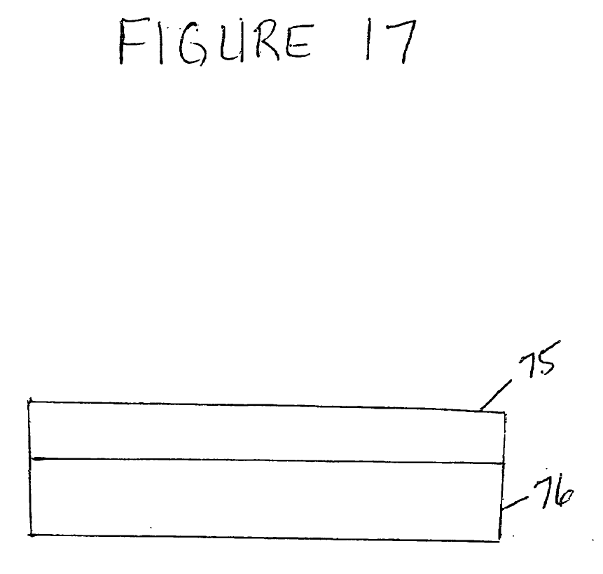

FIG. 17 depicts a fracture control layer 75 on a freestanding nitride epitaxial layer 76. Fracture control layer 75 has different cleave planes than epitaxial layer 76. In this manner, fracture control layer 75 can be used to toughen the epitaxial layer 76 for improved liftoff, handling, and/or scribe and break. More preferably, fracture control layer 75 is a transparent oxide. Even more preferably, fracture control layer 75 is greater than 3000 angstroms thick. Most preferred is that fracture control layer 75 is a doped ZnO or ZnO alloy and the epitaxial layer 76 is a nitride alloy. The added thickness of the ZnO maintains good optical properties.

While the invention has been described with the inclusion of specific embodiments and examples, it is evident to those skilled in the art that many alternatives, modifications and variations will be evident in light of the foregoing descriptions. Accordingly, the invention is intended to embrace all such alternatives, modifications and variations that fall within the spirit and scope of the appended claims.

1. A semiconductor structure comprising
a HVPE grown nitride template of indium gallium nitride being at least 15 microns thick.

2. The semiconductor structure of claim 1 wherein said HVPE grown nitride template is in a light emitting device, and wherein said HVPE grown nitride template provides a substantially continuously varying output spectrum across the surface of said light emitting device.

3. The semiconductor structure of claim 2 further comprising
a light source having at least one of said light emitting devices.

4. The semiconductor structure of claim 1 wherein said HVPE grown nitride template is in a solar cell, and wherein said HVPE grown nitride template provides a substantially continuously varying absorption spectrum across the surface of said solar cell.

5. The semiconductor structure of claim 4 further comprising
a solar collector having at least one of said solar cells, a wavelength dependent element, and a collection/collimating optical system.

6. The semiconductor structure of claim 1 further comprising
a light emitting diode having said HVPE grown nitride template, said light emitting diode emitting light with a FWHM greater than 100 nm between 420 nm and 800 nm.

7. The semiconductor structure of claim 1 further comprising
a light source having a blue light emitting diode, a luminescent element and a red light emitting diode having said HVPE grown nitride template.

8. The semiconductor structure of claim 1 further comprising
a light recycling cavity having at least one light emitting diode, said at least one light emitting diode having said HVPE grown nitride template.

9. The semiconductor structure of claim 1 further comprising
said HVPE grown nitride template being a freestanding HVPE grown nitride template; and
an epitaxial chip grown light emitting diode formed on said HVPE grown nitride template, said epitaxial grown light emitting diode having a top transparent contact and a bottom transparent contact.

10. The semiconductor structure of claim 9 further comprising
a stack of at least two epitaxial chip grown light emitting diodes.

11. The semiconductor structure of claim 1 further comprising
said HVPE grown nitride template being a freestanding HVPE grown nitride template; and
a fracture control layer formed on said freestanding HVPE grown nitride template.

12. The semiconductor structure of claim 11 wherein said fracture control layer is a transparent oxide.

13. The semiconductor structure of claim 11 wherein said fracture control layer has a substantially different cleave plane than said freestanding HVPE grown nitride template.

14. The semiconductor structure of claim 11 wherein said fracture control layer is a transparent conductive oxide.

15. The semiconductor structure of claim 11 wherein said fracture control layer is an undoped ZnO, a doped ZnO, an undoped ZnO alloy or a doped ZnO alloy.

16. The semiconductor structure of claim 11 wherein said fracture control layer is greater than 3000 Angstroms thick.

17. The semiconductor structure of claim 1 further comprising
a double side polished sapphire substrate; and
said HVPE grown nitride template formed on said double side polished sapphire substrate; said HVPE grown nitride template having substantially no backside growth on said double side polished sapphire substrate.

18. The semiconductor structure of claim 1 further comprising
a double side polished sapphire substrate; and
said HVPE grown nitride template formed on said double side polished sapphire substrate; said HVPE grown nitride template having a surface roughness less than 100 Angstroms on a 5 micron×5 micron field on the outer surface of said HVPE grown nitride template.

19. The semiconductor structure of claim 18 wherein said HVPE grown nitride template is removed from said double side polished sapphire substrate to form a freestanding HVPE grown nitride template.

20. The semiconductor structure of claim 1 further comprising
a double side polished sapphire substrate; and
said HVPE grown nitride template formed on said double side polished sapphire substrate, wherein a 2 inch wafer of said HVPE grown nitride template exhibits less than 100 microns bow at room temperature.

21. The semiconductor structure of claim 20 wherein said HVPE grown nitride template is removed from said double side polished sapphire substrate to form a freestanding HVPE grown nitride template.

22. The semiconductor structure of claim 20 wherein said HVPE grown nitride template has less than 100 microns of absolute bow between 25 and 1050 degrees C.

23. The semiconductor structure of claim 20 wherein said HVPE grown nitride template has less than 50 microns of absolute bow at liftoff temperature and has essentially a flat surface at reactor growth temperature.

24. A method for scribing and liftoff comprising
forming a HVPE grown nitride template of indium gallium nitride being at least 15 microns thick on a transparent substrate;
transmitting a laser line source through said transparent substrate to a surface of said HVPE grown nitride template, said laser line source scanning said HVPE grown nitride template in two substantially different directions to scribe said surface of said HVPE grown nitride template and to physically separate said HVPE grown nitride template from said transparent substrate.

25. A method of forming a variable output nitride device comprising
exposing a growth surface of a HVPE grown nitride template of indium gallium nitride being at least 15 microns thick to an irradiating means prior to subsequent growth on said growth surface.

26. The method of forming a variable output nitride device of claim 25 wherein said irradiating means is an actinic source of laser, electron, x-ray, radiation sources, plasmas, reactive ions, or atomic species.

26. The method of forming a variable output nitride device of claim 25 wherein said HVPE grown nitride template being a freestanding HVPE grown nitride template.

27. A method of forming a variable output nitride device comprising
exposing a growth surface of a HVPE grown nitride template of indium gallium nitride being at least 15 microns thick to an irradiating means prior to subsequent growth on said growth surface.

28. The method of forming a variable output nitride device of claim 27 wherein said irradiating means is an actinic source of laser, electron, x-ray, radiation sources, plasmas, reactive ions, or atomic species.

29. The method of forming a variable output nitride device of claim 27 wherein said HVPE grown nitride template being a freestanding HVPE grown nitride template.

30. The method of forming a variable output nitride device of claim 27 further comprising
exposing both surfaces of said HVPE grown nitride template to an irradiating means prior to subsequent growth on said growth surface.
